(19) United States
(12) Patent Application Publication
(10) Pub. No.: US 2010/0213541 A1
(43) Pub. Date: Aug. 26, 2010

(54) SEMICONDUCTOR DEVICE HAVING RECESS CHANNEL STRUCTURE

(75) Inventors: In-sang Jeon, Seoul (KR); Si-hyung Lee, Gyeonggi-do (KR); Jong-ryeol Yoo, Gyeonggi-do (KR); Yu-gyun Shin, Gyeonggi-do (KR); Suk-hun Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/699,650

(22) Filed: Feb. 3, 2010

(30) Foreign Application Priority Data
Feb. 24, 2009 (KR) 10-2009-0015389

(51) Int. Cl. H01L 29/78

(52) U.S. Cl. 257/334; 257/E29.262

(57) ABSTRACT

An integrated circuit device includes a semiconductor substrate including an active region defined by an isolation region and having at least one trench therein, a gate insulating layer formed in the at least one trench, a gate electrode layer having a nano-crystalline structure disposed on the gate insulating layer and a word line on the gate electrode layer in the at least one trench. The device may further include a capping layer on the word line.

### CROSS-REFERENCE TO RELATED APPLICATIONS

This application claims the benefit of Korean Patent Application No. 10-2009-0015389, filed on Feb. 24, 2009, in the Korean Intellectual Property Office, the disclosure of which is incorporated herein in its entirety by reference.

### BACKGROUND

The inventive subject matter relates to a semiconductor device, and more particularly, to a semiconductor device having a recess channel structure.

Currently, research is being conducted on a buried word line cell array transistor (BCAT) in which word lines are buried below the surface of a silicon substrate by using metal, instead of polysilicon, for a gate electrode in a recess channel array transistor (RCAT). Unlike a polysilicon gate of a conventional dynamic random access memory (DRAM), the word lines may be formed at small intervals due to the BCAT technology, and thus a cell area may be decreased. However, due to impurities such as fluorine (F) penetrating when a metal gate is formed, an oxide layer may deteriorate and a leakage current may occur.

### SUMMARY

According to some aspects of the inventive subject matter, an integrated circuit device includes a semiconductor substrate including an active region defined by an isolation region and having at least one trench therein, a gate insulating layer formed in the at least one trench, a gate electrode layer having a nano-crystalline structure disposed on the gate insulating layer and a word line on the gate electrode layer in the at least one trench. The device may further include a capping layer on the word line.

In some embodiments, the gate electrode layer has a resistivity of from about 100 μΩ-cm to about 1000 μΨ-cm. The gate electrode layer may include, for example, a titanium nitride (TiN) layer, a titanium carbide (TiC) layer, titanium carbon nitride (TiCN) layer, a tantalum nitride (TaN) layer, a tantalum carbide (TaC) layer, a tantalum carbon nitride (TaCN) layer, a tungsten nitride (WN) layer, a tungsten carbide (WC) layer, a tungsten carbon nitride (WCN) layer, a titanium/titanium nitride (Ti/TiN) layer, a tantalum/tantalum nitride (Ta/TaN) layer, a tungsten/tungsten nitride (W/WN) layer, a titanium silicon nitride (TiSiN) layer, a tantalum silicon nitride (TaSiN) layer and/or a tungsten silicon nitride (WsiN) layer. The gate insulating layer may include a silicon oxide (SiO₂) layer and a silicon nitride (SiN) layer. The gate insulating layer may include a silicon oxide layer having a nitrified surface. The word line may include aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn) and/or zirconium (Zr). The word line may include a silicide material.

Further embodiments of the inventive subject matter provide an integrated circuit device including a substrate including an active region defined by an isolation region and having at one trench therein, a gate insulating layer in the at least one trench, a gate electrode layer having a nano-crystalline structure on the gate insulating layer and a buried word line comprising a lower buried word line on a bottom surface of the gate electrode layer and an upper buried word line formed on an upper surface of the gate electrode layer and comprising a material different from a material of the lower buried word line.

Additional embodiments of the inventive subject matter provide an integrated circuit device including a substrate comprising an active region defined by an isolation region and having at least one trench therein, a gate insulating layer fin the at least one trench, a gate electrode layer having a nano-crystalline structure disposed on the gate insulating layer, a word line on the gate electrode layer, filling the at least one trench and extending on an adjacent surface of the substrate; a capping layer on the word line and a spacer on a sidewall of the word line.

### BRIEF DESCRIPTION OF THE DRAWINGS

Exemplary embodiments of the inventive subject matter will be more clearly understood from the following detailed description taken in conjunction with the accompanying drawings in which:

FIG. 1 is a diagram showing an exemplary planar arrangement of word lines according to some embodiments of the inventive subject matter;

FIGS. 2A through 2F are cross-sectional diagrams illustrating operations for manufacturing a semiconductor device having a recess channel structure according to some embodiments of the inventive subject matter;

FIGS. 3A and 3B are diagrams illustrating operations for blocking fluorine (F) atoms formed due to a gate electrode layer having a nano-crystalline structure according to some embodiments of the inventive subject matter;

FIG. 4 is a cross-sectional diagram of a semiconductor device having a recess channel structure according to some embodiments of the inventive subject matter: and

FIG. 5 is a cross-sectional diagram of a semiconductor device having a recess channel structure according to some embodiments of the inventive subject matter.

### DETAILED DESCRIPTION OF EMBODIMENTS

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on”, “connected to” or “coupled to” another element, it may be directly on, connected or coupled to the other element or intervening elements may be present. In contrast, when an element is referred to as being “directly on”, “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above”, “upper”, “beneath”, “below”, “lower”, and the like, may be used herein for ease of description to describe one element or feature's relationship to another element(s) or feature (s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a”, “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the inventive subject matter will be described in detail with reference to the accompanying drawings. In the drawings, variations from the shapes of the illustrations as a result, for example, of manufacturing techniques and/or tolerances, are to be expected. Thus, the example embodiments should not be construed as limited to the particular shapes of regions illustrated herein but may be to include deviations in shapes that result, for example, from manufacturing.

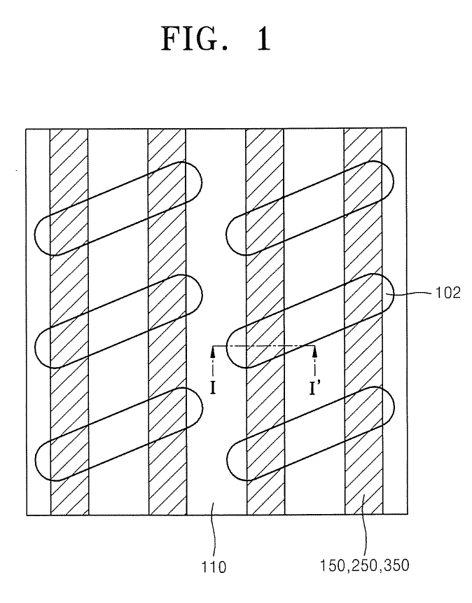

FIG. 1 is a diagram showing an exemplary layout of a planar arrangement of a plurality of word lines 150, 250, and 350 for forming a gate, which are realized by using operations for manufacturing a semiconductor device according to some embodiments of the inventive subject matter. Referring to FIG. 1, the word lines 150, 250, and 350 extend over a plurality of island shape active regions 102 formed in a cell array region of a semiconductor layer 100, and a device isolation region 110 that defines the active regions 102 in a predetermined direction. Each of the word lines 150, 250, and 350 may be buried in the cell array region of the semiconductor layer 100. However, the active regions 102 and the word lines 150, 250, and 350 are not limited to shapes and configurations illustrated in FIG. 1 and various shapes and arrangements are acceptable within the scope of the inventive subject matter.

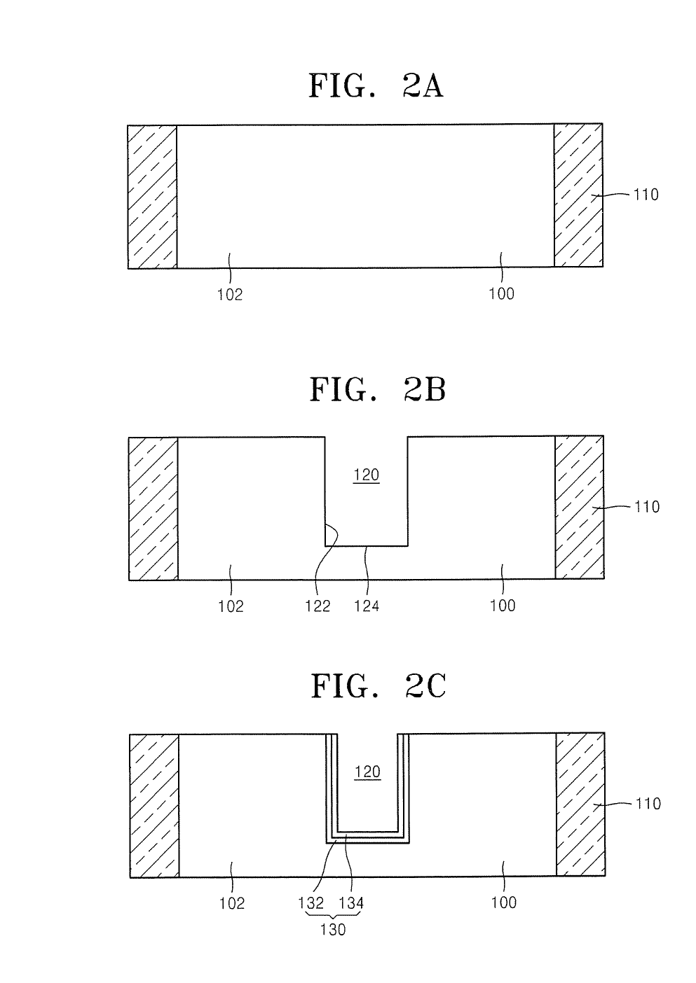

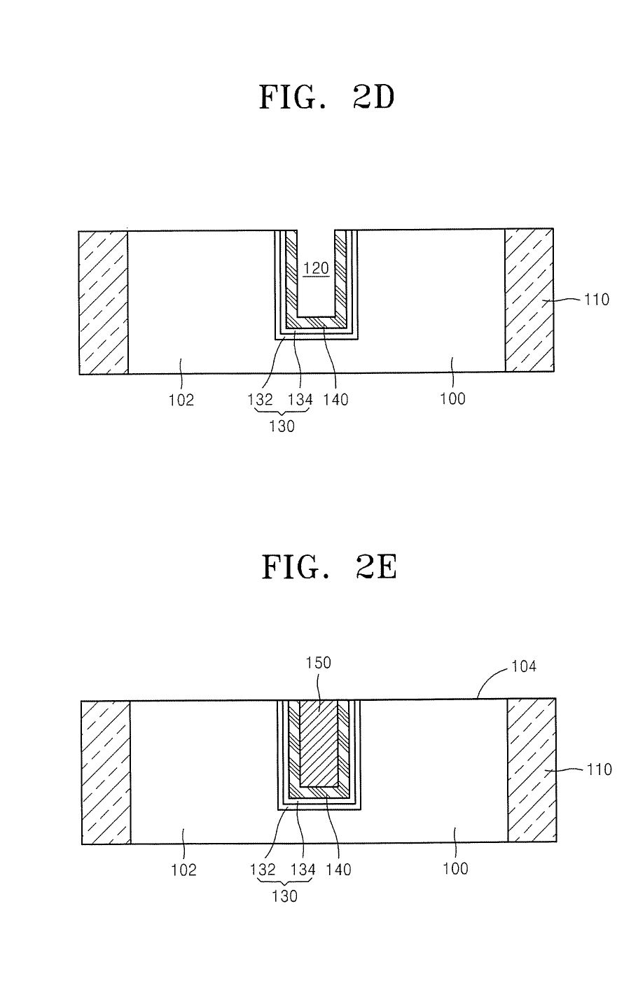

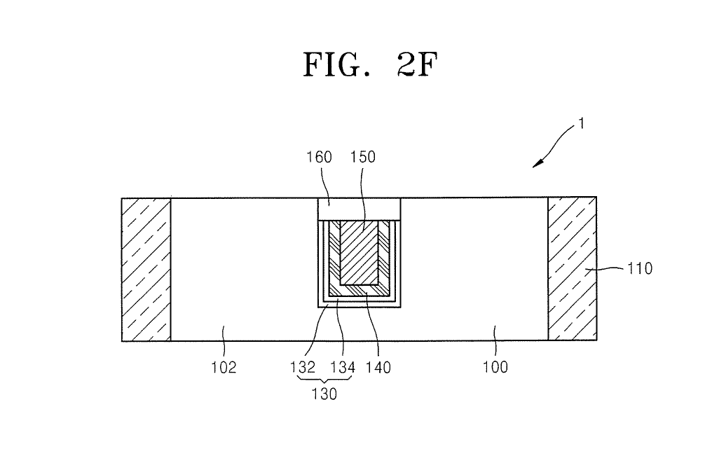

Hereinafter, operations for manufacturing a semiconductor device according to some embodiments of the inventive subject matter will now be described with reference to the structure including word lines 150, 250, and 350 illustrated in FIG. 1. FIGS. 2A through 2F are cross-sectional diagrams for sequentially describing operations for manufacturing a semiconductor device 1 having a recess channel structure, according to some embodiments of the inventive subject matter. FIGS. 2A through 2F correspond to a cross section taken along a line I-I′ illustrated in FIG. 1.

Referring to FIG. 2A, a device isolation region 110 for defining an active region 102 is formed in a semiconductor layer 100. The semiconductor layer 100 may include a substrate having a semiconductor such as silicon (Si) or silicon-germanium (SiGe), an epitaxial layer, a silicon-on-insulator (SOI) layer, or a semiconductor-on-insulator (SEOI) layer. The device isolation region 110 may be a shallow trench isolation (STI) region for improving speed and integration of the semiconductor device 1 and may contain, for example, at least one of silicon oxide, silicon nitride, and silicon oxynitride. However, the inventive subject matter is not limited thereto.

Referring to FIG. 2B, a trench 120 for forming a recess channel is formed in the active region 102 defined by the device isolation region 110. Since one or more recess channels may be formed in the active region 102, a plurality of trenches 120 may be formed in the active region 102. Also, the trench 120 may be formed to have a width, for example, from about 10 nm to about 200 nm, or to have a width, for example, less than about 50 nm. If follow-up processes are performed, a recess channel region is formed in the semiconductor layer 100 around the trench 120. An etching process for forming the trench 120 may be, for example, a sloped etching process or an anisotropy etching process such as a reactive ion etching (RIE) or a plasma etching process. However, the inventive subject matter is not limited thereto.

Also, although not illustrated in FIG. 2B, in order to form the trench 120, for example, a buffer insulating layer having silicon oxide may be formed on the semiconductor layer 100. Also, for example, a hard mask layer having polysilicon or silicon nitride may be formed. The buffer insulating layer and the hard mask layer are well known in the art and thus descriptions thereof will be omitted here. Also, descriptions of layers such as a sacrificial layer, a buffer layer, a pad layer, and a hard mask layer, which are formed by using, for example, a deposition process and are removed by using, for example, an etching process in order to form layers in or on a gate, will be omitted here.

Referring to FIG. 2C, a gate insulating layer 130 is formed on the surface of the trench 120, i.e., side surfaces 122 and a bottom surface 124 of the trench 120. Also, the gate insulating layer 130 may be, for example, a multilayer having a stacked structure of a silicon oxide layer 132 and a silicon nitride layer 134. Also, the gate insulating layer 130 may be a silicon oxide layer of which surface is nitrified by performing a nitrification process.

The silicon oxide layer 132 may be formed by using one of various processes, such as a thermal oxidation process, a rapid thermal oxidation (RTO) process, a chemical vapor deposition (CVD) process, a plasma enhanced CVD (PECVD) process, a high density plasma CVD (HDP-CVD) process, and a sputtering process. The silicon nitride layer 134 may be formed by using one of various processes such as a CVD process, a PECVD process, a HDP-CVD process, a digital CVD process, a pulsed CVD process, a HDP-CVD process, an atomic layer deposition (ALD) process, and a sputtering process.

The nitrification process may be performed by using various processes, such as a rapid thermal annealing (RTA) process, a spike RTA process, a millisecond RTA process, and a laser RTA process using a nitrogen-containing gas such as a NH₃ gas. Also, the nitrification process may be performed by using one of various processes such as a plasma nitrification process, a plasma ion injection process, a PECVD process, a HDP-CVD process, and a radical nitrification process. After performing the nitrification process, the semiconductor layer 100 may be thermally processed in an inactive atmosphere having an inert gas such as helium (He) or argon (Ar). The silicon nitride layer 134 or the nitrified surface of the gate insulating layer 130 is formed to face a gate electrode layer 140 to be formed in a follow-up process. An insulating layer formed on a top surface of the semiconductor layer 100 may be removed by using, for example, an etching process, which description thereof will be omitted.

Referring to FIG. 2D, the gate electrode layer 140 is formed on the surface of the gate insulating layer 130. The gate electrode layer 140 may be formed by using, for example, a CVD process, a PECVD process, a HDP-CVD process, a sputtering process, a metal organic CVD (MOCVD) process, or an ALD process. The gate electrode layer 140 entirely or at least partially has a nano-crystalline structure and may have a resistivity of from about 100 μΩ-cm to about 1000 μΩ-cm. The gate electrode layer 140 may be formed by using a material having a halogen element such as chlorine (Cl) (for example, TiCl₄) or by using a material not having a halogen element. The gate electrode layer 140 having a nano-crystalline structure will be described in detail later.

Referring to FIG. 2E, a word line 150 is formed on the gate electrode layer 140 so as to fill the trench 120. The word line 150 may be formed by using, for example, a CVD process, a PECVD process, a HDP-CVD process, a sputtering process, or an ALD process. The word line 150 may contain at least one of polysilicon, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt). rhodium (Rh), rhenium (Re), ruthenium (Ru), tantalum (Ta), tellurium (Te), titanium (Ti), tungsten (W), zinc (Zn), and zirconium (Zr). Also, the word line 150 may further contain nitride or silicide. The silicide may be cobalt silicide (CoSiₓ), nickel silicide (NiSiₓ), titanium silicide (TiSiₓ), tungsten silicide (WSiₓ), or tantalum silicide (TaSiₓ) but is not limited thereto. For example, the above-mentioned silicide materials may have a resistivity equal to or less than 300 μΩ-cm.

In the illustrated embodiments, upper surfaces of the gate insulating layer 130, the gate electrode layer 140, and the word line 150 formed on the surface of the gate electrode layer 140 are completely buried in the semiconductor layer 100 so as not to protrude from the surface of the semiconductor layer 100. The buried word line 150 may be formed as follows. Initially, a word line layer (not shown) is formed on the semiconductor layer 100 and the gate electrode layer 140 so as to fill the trench 120. Then, the word line layer is polished so as to expose an upper surface 104 of the semiconductor layer 100. The polishing process may be an etch-back process or a chemical mechanical polishing (CMP) process.

Referring to FIG. 2F, the gate insulating layer 130, the gate electrode layer 140, and the word line 150 in the trench 120 are recessed into the trench 120 by using, for example, a partial etching process, so as to form a recess. Then, a capping layer 160 is optionally formed on the gate insulating layer 130, the gate electrode layer 140, and the word line 150 in the recess. The capping layer 160 is formed by using, for example, a CVD process. The capping layer 160 may fill the recessed region and may not protrude from the surface of the semiconductor layer 100. The capping layer 160 may contain an insulating material, such as silicon oxide or silicon nitride. However, the inventive subject matter is not limited to the above-described operations or structures of the recessed region and the capping layer 160. For example, although not illustrated in FIG. 2F, only the word line 150 may be recessed and the capping layer 160 may be formed on the word line 150, or only the gate electrode layer 140 and the word line 150 may be recessed and the capping layer 160 may be formed on the gate electrode layer 140 and the word line 150. By performing the above-described processes and by further performing the follow-up processes if necessary, the semiconductor device 1 may be formed.

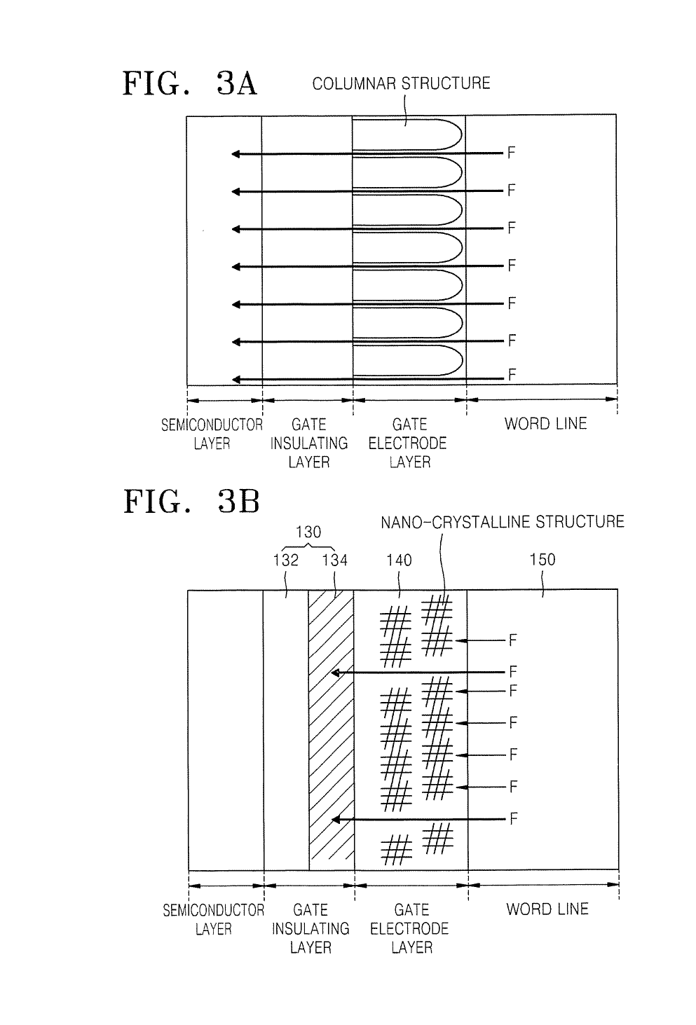

FIGS. 3A and 3B are diagrams for describing a process of blocking fluorine (F) atoms formed due to a gate electrode layer having a nano-crystalline structure according to some embodiments of the inventive subject matter. FIG. 3A illustrates comparative examples that include a titanium nitride (TiN) layer having a columnar structure. FIG. 3B illustrates an example of the inventive subject matter, which includes a gate electrode layer 140 having a nano-crystalline structure.

Referring to FIG. 3A, the TiN layer is formed in a columnar structure, as a gate electrode layer. Then, if a word line is formed by using, for example. W, generally, an F-containing gas such as WF₆ is used. When the word line is formed, fluorine (F) atoms or ions are decomposed from WF₆ and penetrate into the gate electrode layer (see arrows). The columnar structure of the gate electrode layer generally is not a compact structure and thus the fluorine (F) may penetrate to reach the gate insulating layer formed of silicon oxide. When the fluorine (F) contacts the silicon oxide, an equivalent oxide thickness (EOT) may be increased by reducing permittivity of the silicon oxide, a leakage current is increased by breaking coupling of oxygen and Si (Si—O) in the gate insulating layer and/or coupling of Si and Si (Si—Si). In addition, if a large amount of the fluorine (F) penetrates into the gate electrode layer formed of silicon oxide, charge mobility may be decreased by increasing surface coupling between a silicon substrate and the silicon oxide. Accordingly, penetration of the fluorine (F) may damage the gate insulating layer and may also deteriorate a semiconductor device.

Referring to FIG. 3B, the gate electrode layer 140 is formed in a nano-crystalline structure. The nano-crystalline structure is a compact structure and thus penetration of the fluorine (F) decomposed when a word line 150 is formed may be significantly blocked (see short arrows). In addition, if a gate insulating layer 130 further includes a silicon nitride layer 134, penetration of the fluorine (F) through the gate electrode layer 140 may further be blocked (see long arrows). As such, damage of a silicon oxide layer 132 due to the penetration of the fluorine (F) may be reduced or prevented. Also, the silicon nitride layer 134 may also block penetration of chlorine (Cl), used for forming the gate electrode layer 140, into the gate insulating layer 130.

In general, the gate electrode layer 140 has a columnar structure in which a material for forming the gate electrode layer 140, for example, TiN, grows in a predetermined direction such as the <200> direction. However, the gate electrode layer 140 may have an amorphous structure by varying process conditions such as growing rate, deposition temperature, gas flow amount, and gas flow rate. However, the amorphous structure generally has a resistivity of several to several tens of Ω-cm. On the other hand, according to some embodiments of the inventive subject matter, the gate electrode layer 140 in a nano-crystalline structure has a resistivity of from about 100 μΩ-cm to about 1000 μΩ-cm. In a comparative example, the TiN layer in a columnar structure has a resistivity of from about 100 μΩ-cm to about 200 μΩ-cm. The size of crystal grains in the nano-crystalline structure may be, for example, from about 1 Å to about 50 Å. However, the inventive subject matter is not limited thereto. The nano-crystalline structure may be formed by using an MOCVD process or an ALD process. For example, the nano-crystalline structure may be formed by carrying a Ti-containing precursor into an MOCVD chamber through a carrier gas, for example, an inert gas such as He and by making the precursor to react to a nitrogen-containing gas such as NH₃. In this case, the temperature in the chamber may be maintained to be less than a temperature for forming the columnar structure and greater than a temperature for forming the amorphous structure. Table 1 shows exemplary results measured in order to compare characteristics of a TiN layer having a columnar structure and a TiN layer having a nano-crystalline structure.

TABLE 1

| | TiN Layer in | TiN Layer in |
|---|---|---|
| | Columnar | Nano-crystalline |
| | Structure | Structure |
| Resistivity [μΩ-cm] | 120 | 300 |
| Equivalent Oxide Thickness [Å] | 0.88 | 0.29 |
| Trap Density in Silicon Oxide | 1.03 × 10¹¹ | 1.87 × 10¹⁰ |
| Layer [pcs/cm²] | | |
| Trap Density in Interface between | 3.47 × 10¹¹ | 5.42 × 10¹¹ |
| Silicon and Silicon Oxide Layer | | |
| [pcs/cm²] | | |

Referring to Table 1, the TiN layer in a nano-crystalline structure has a resistivity of about 300 μΩ-cm, which is greater than the resistivity of the TiN layer in a columnar structure (about 120 μΩ-cm), is less than the resistivity of the above described amorphous structure (several to several tens of μΩ-cm), and is in a range of values suitable for a semiconductor device. Also, with respect to an equivalent oxide thickness and a trap density in a silicon oxide layer (i.e., the gate insulating layer 130 illustrated in FIGS. 2C through 2F), the TiN layer in a nano-crystalline structure has excellent characteristics in comparison to the TiN layer in a columnar structure. With respect to a trap density in an interface between silicon (i.e., the semiconductor layer 100 illustrated in FIGS. 2A through 2F) and a silicon oxide layer (i.e., the gate insulating layer 130 illustrated in FIGS. 2C through 2F), the TiN layers are in similar ranges of values.

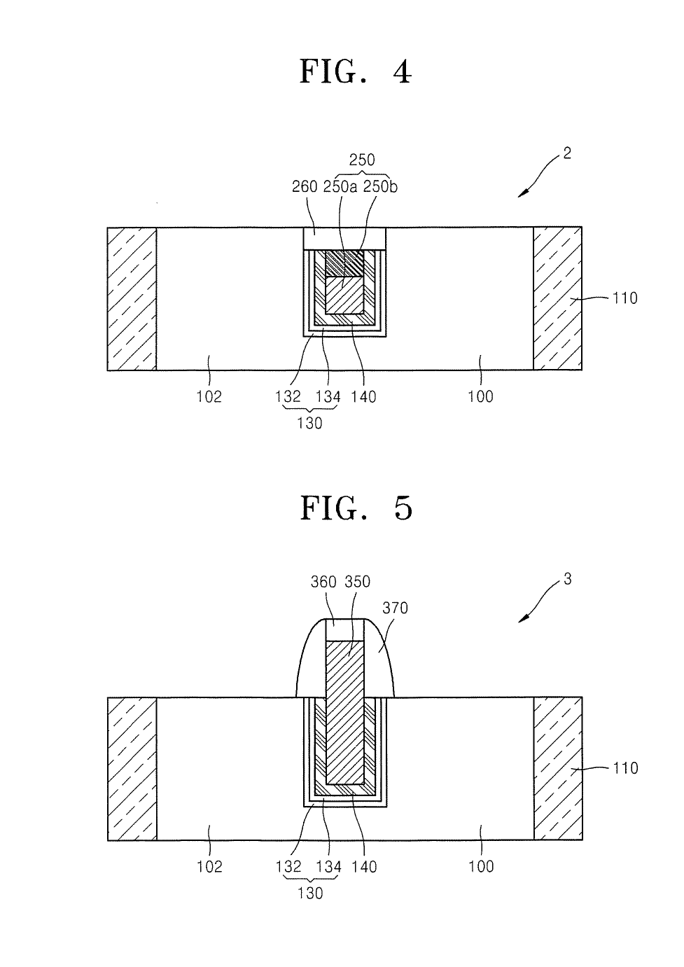

FIG. 4 is a cross-sectional diagram of a semiconductor device 2 having a recess channel structure, according to another embodiment of the inventive subject matter. Regarding FIG. 4, similar descriptions presented in the above embodiments will not be repeated.

Referring to FIG. 4, a buried word line 250 includes a lower buried word line 250a formed on a lower surface of the gate electrode layer 140, and an upper buried word line 250b formed on an upper surface of the gate electrode layer 140 by using a material different from a material for forming the lower buried word line 250a.

The lower buried word line 250a may be formed as described below. Initially, a first word line layer (not shown) is formed on a semiconductor layer 100 so as to fill a trench 120. Then, the first word line layer is polished by using an etch-back process or a CMP process so as to expose the surface of the semiconductor layer 100. The lower buried word line 250a is formed by recessing the polished first word line layer into the semiconductor layer 100.

Then, the upper buried word line 250b may be formed as described below. A second word line layer (not shown) is formed on the semiconductor layer 100 so as to fill the trench 120 in which the lower buried word line 250a is formed. Then, the second word line layer is polished by using an etch-back process or a CMP process so as to expose the surface of the semiconductor layer 100. The upper buried word line 250b is formed by recessing the polished second word line layer into the semiconductor layer 100. A capping layer 260 is formed on the upper buried word line 250b. Processes of and materials for forming the word line 150 illustrated FIGS. 2E and 2F may be used to form the lower buried word line 250a and the upper buried word line 250b.

As such, the lower buried word line 250a and the upper buried word line 250b formed of different materials may reduce resistance of the buried word line 250. Also, in comparison to a case when the entire buried word line 250 is formed of silicide, a diffusion length may be decreased and thus the buried word line 250 may be easily controlled. Also, if the lower buried word line 250a is formed of polysilicon, an aspect ratio may be decreased and thus metal for forming the upper buried word line 250b may be easily deposited.

FIG. 5 is a cross-sectional diagram of a semiconductor device 3 having a recess channel structure, according to another embodiment of the inventive subject matter. Regarding FIG. 5. similar descriptions presented in the above embodiments will not be repeated.

Referring to FIG. 5, the semiconductor device 3 includes a word line 350 formed on a gate electrode layer 140 that is formed as described above with reference to FIG. 2D. The word line 350 is formed to fill a trench 120 and to protrude on the surface of a semiconductor layer 100. Also, a capping layer 360 is formed on a top surface of a protruding portion of the word line 350 and a spacer 370 is formed on side surfaces of the protruding portion of the word line 350. The capping layer 360 and the spacer 370 may contain an insulating material such as silicon oxide and/or silicon nitride.

The above embodiments have been described with respect to a recess channel array transistor (RCAT) structure and a process of forming the RCAT structure based on the layout illustrated in FIG. 1. However, shapes and arrangements of active regions and word lines are not limited to those shown in the layout illustrated in FIG. 1 and the shapes and arrangements may be variously changed within the scope of the technical idea of the inventive subject matter. For example, the inventive subject matter may be applied to manufacture various semiconductor devices such as dynamic random access memory (DRAM) devices, static random access memory (SRAM) devices, and non-volatile memory devices.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed is:

1. An integrated circuit device comprising:
a semiconductor substrate including an active region defined by an isolation region and having at least one trench therein;
a gate insulating layer formed in the at least one trench;
a gate electrode layer having a nano-crystalline structure disposed on the gate insulating layer; and
a word line on the gate electrode layer in the at least one trench.

2. The device of claim 1, wherein the gate electrode layer has a resistivity of from about 100 μΩ-cm to about 1000 μΩ-cm.

3. The device of claim 1, wherein the gate electrode layer comprises a titanium nitride (TiN) layer, a titanium carbide (TiC) layer, titanium carbon nitride (TiCN) layer, a tantalum nitride (TaN) layer, a tantalum carbide (TaC) layer, a tantalum carbon nitride (TaCN) layer, a tungsten nitride (WN) layer, a tungsten carbide (WC) layer, a tungsten carbon nitride (WCN) layer, a titanium/titanium nitride (Ti/TiN) layer, a tantalum/tantalum nitride (Ta/TaN) layer, a tungsten/tungsten nitride (W/WN) layer, a titanium silicon nitride (TiSiN) layer, a tantalum silicon nitride (TaSiN) layer and/or a tungsten silicon nitride (WsiN) layer.

4. The device of claim 1, wherein the gate insulating layer comprises a silicon oxide (SiO₂) layer and a silicon nitride (SiN) layer.

5. The device of claim 1, wherein the gate insulating layer comprises a silicon oxide layer having a nitrified surface.

6. The device of claim 1, wherein the word line comprises aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn) and/or zirconium (Zr).

7. The device of claim 1, wherein the word line comprises a silicide material.

8. The device of claim 1, further comprising a capping layer on the word line.

9. An integrated circuit device comprising:
a substrate including an active region defined by an isolation region and having at one trench therein;
a gate insulating layer in the at least one trench;
a gate electrode layer having a nano-crystalline structure on the gate insulating layer; and
a buried word line comprising a lower buried word line on a bottom surface of the gate electrode layer and an upper buried word line formed on an upper surface of the gate electrode layer and comprising a material different from a material of the lower buried word line.

10. An integrated circuit device comprising:
a substrate comprising an active region defined by an isolation region and having at least one trench therein;
a gate insulating layer fin the at least one trench:
a gate electrode layer having a nano-crystalline structure disposed on the gate insulating layer;
a word line on the gate electrode layer, filling the at least one trench and extending on an adjacent surface of the substrate;
a capping layer on the word line; and
a spacer on a sidewall of the word line.
